(19) United States
(12) Patent Application Publication
(10) Pub. No.: US 2026/0112659 A1
(43) Pub. Date: Apr. 23, 2026

(54) FUEL CELL INCLUDING A MICROCHANNEL DESIGN METHOD BASED ON AN OPTIMAL DESIGN ALGORITHM FOR CHANNEL SPACING AND A SEPARATOR DESIGNED USING IT

(71) Applicant: Pusan National University Industry-University Cooperation Foundation, Busan (KR)

(72) Inventors: Eun Seop YEOM, Busan (KR); Se Hyeon AN, Busan (KR)

(21) Appl. No.: 19/362,127

(22) Filed: Oct. 17, 2025

(30) Foreign Application Priority Data
Oct. 21, 2024 (KR) 10-2024-0143968

(51) Int. Cl. H01M 8/0263; G06F 30/28; H01M 8/12; H01M 8/1253

(52) U.S. Cl. CPC H01M 8/0263; G06F 30/28; H01M 8/1253; H01M 2008/1293

(57) ABSTRACT

A present disclosure provides a method for designing a microchannel using a channel gap optimal design algorithm and a fuel cell including a separator designed using the same. The fuel cell including the separator designed using the method for designing a microchannel using a channel gap optimal design algorithm can be designed by calculating an optimal channel gap through the algorithm, and through the designed optimal channel gap, temperature reduction of a fluid, temperature distribution, and flow distribution uniformity can be improved.

### CROSS-REFERENCE TO RELATED APPLICATION

The present application claims priority under 35 U.S.C. § 119(a) to Korean Patent Application No. 10-2024-0143968 filed in the Korean Intellectual Property Office on Oct. 21, 2024, which is incorporated herein by reference in its entirety.

### TECHNICAL FIELD

The present invention relates to a microchannel design method using an optimal channel spacing design algorithm for improving fluid temperature reduction, temperature distribution and flow distribution uniformity, and a fuel cell including a separator designed using the same.

### BACKGROUND ART

As environmental regulations are strengthened, interest in a fuel cell, which is a device that generates current through an electrochemical reaction of hydrogen and oxygen, is rapidly increasing, and the fuel cell has an advantage in that it can significantly reduce CO₂ emissions, unlike the process of converting conventional fossil fuels into electrical energy.

In addition, there are various types of fuel cells depending on the material of the electrolyte constituting the fuel cell. Among them, a solid oxide fuel cell (SOFC) uses a solid oxide electrolyte, and thus, unlike a polymer electrolyte fuel cell, it does not use an expensive platinum catalyst.

In addition, SOFC has a high operating temperature of 600 to 1000° C. due to the ionic conductivity of the electrodes and electrolyte, and has a high power generation efficiency (53˜65%) compared to other fuel cells.

In addition, since the product water inside the cell flows in a single gas phase, it does not require a high pressure to remove it, and combined heat and power using waste heat generated during operation of the fuel cell is possible, resulting in a high overall system efficiency (70 to 80%).

Such an SOFC is composed of a PEN (Positive electrode-Electrolyte-Negative Electrode) structure made of an electrode part and an electrolyte, and is wrapped by separators at both ends to form a single unit (cell). The shape of the flow path is determined by the rib shape of the separator, and it is manufactured in the form of a layers in which the units are layered to meet the required output power.

At this time, a manifold is used for uniform distribution of reactants in the layers, and it is divided into an internal manifold and an external manifold according to the manifold coupling method.

Generally, an internal manifold structure is mainly used due to the ease of sealing to prevent reactant leakage. In the internal manifold, reactants flow directly into the inlet of each cell, so it is known that the performance deteriorates due to non-uniform distribution of reactants at high flow rates.

Accordingly, the channel shape of the SOFC has a great influence on the output power performance, so research on this has been steadily conducted.

Due to the high temperature and temperature gradient inside the cell, degradation caused by thermal expansion and delamination between components have a fatal impact on the long-term stable operation of the SOFC, and thus, studies on the shape of internal manifolds for improving flow uniformity of reactants inside the cell have been continuously conducted.

At this time, the uniformity of the reactants generally refers to the uniformity of the inflow of reactants of all channels with respect to a channel which is a path through which the reactants pass after passing through a header.

In the internal manifold layers, after the reactant flows into each cell, it passes through the header and is spread throughout the cell. In general, obstacles such as vanes and ridges are installed in the flow path to more efficiently distribute the reactant.

However, in order to install the accessory parts inside the flow path, a sufficient space must be secured at the inlet of the flow path, which makes the length of the cell longer.

At this time, as the cell becomes longer, the temperature inside the cell increases, and there is a problem that it has a trade-off relationship with performance improvement due to increased uniformity of reactants.

Therefore, the installation of ancillary parts such as obstacles in the internal manifold causes the temperature of the cell to increase, which leads to a decrease in the performance of the SOFC. That is, there is a need to optimize the shape of the cell without using ancillary parts.

In addition, the above-mentioned problem is caused by a non-uniform flow, which should be solved not only in the field of fuel cells but also in various fields where the flow distribution affects the performance. For example, a heat exchanger that maintains an appropriate temperature by combining with a device that generates uniform heat is attached to a high-temperature heat source and cools the heat source through a refrigerant such as water. At this time, it is known that the maldistribution of the refrigerant is a factor that reduces not only the efficiency of the heat exchanger but also the efficiency of the system.

### PRIOR ART LITERATURE

### Patent Literature

Registered Patent No. 10-2326087, Republic of Korea

### CONTENTS OF THE INVENTION

### Technical Problem to be Solved

The present invention provides an algorithm for designing an optimal rib-to-rib interval (optimal channel interval) for an internal manifold structure, and a method for optimally designing a flow path using the algorithm.

That is, the present invention is based on a method of improving the uniformity of flow rates flowing into each channel after the reactants introduced into the cell pass through the distribution header, in order to prevent deterioration and peeling phenomena caused by non-uniform temperature distribution and high temperature gradient of a solid oxide fuel cell (SOFC) or a manifold for a heat exchanger using a high-temperature fluid. The present invention is characterized in that the channel intervals are adjusted without using any additional components so that an equal flow rate is introduced into all channels.

Technical subjects achievable from the present invention are not limited to the aforementioned technical subjects and still other technical subjects not described herein may be clearly understood by one of ordinary skill in the art to which the present invention pertains from the following description.

### Means for Solving the Problem

In order to achieve the above technical problem, an embodiment of the present invention provides a fuel cell with an adjusted channel interval of a separator.

A fuel cell with an adjusted channel interval of a separator according to an embodiment of the present invention, comprising: an oxidation electrode; a reduction electrode; an electrolyte positioned between the oxidation electrode and the reduction electrode; and a separator positioned at both ends of the oxidation electrode and the reduction electrode, surrounding the oxidation electrode, the reduction electrode, and the electrolyte, and including a microchannel through which hydrogen gas and oxygen gas move, wherein a channel interval of the microchannel of the separator may be designed by an algorithm defined by the following Equation 1.

$${D}_{h , redeslgn , i} = {C ( \overline{Re} / {Re}_{i} )}^{1 / 3} {D}_{h , i} + {w}_{mg} [ mm ] \qquad [ Equation 1 ]$$

i is the channel number, D_{h,redesign,i} is the newly calculated hydraulic diameter of the i-th channel, C is a correction factor making the sum of actual channel spacing and the sum of calculated channel spacing to be equal, R̅e̅ is the average Reynolds number for all channels, Reᵢ is the Reynolds number of the i-th channel, D_{h,i} is the existing hydraulic diameter of the i-th channel, and w_{mg} is a minimum guaranteed channel width which is the minimum width that ensures the channel does not become narrower than this value, even when the channel width is adjusted.

Also, according to an embodiment of the present invention, the electrolyte is a solid oxide electrolyte material and may include zirconium oxide, gadolinium-doped ceria, or scandia-stabilized zirconia.

Also, according to an embodiment of the present invention, the minimum guaranteed channel interval (w_{mg}) of the channel constituting the microchannel in the separator may be 0.225 mm to 0.25 mm.

According to an embodiment of the present invention, the separator may have an adjustable interval of the distribution header of the fine channel inlet.

Also, according to an embodiment of the present invention, a distance between distribution headers of the fine channel inlet of the separator may be between 0.5 mm and 2.5 mm.

Also, according to an embodiment of the present invention, the microchannel of the separator may have a parallel type, a serpentine type, or a spiral type.

Also, according to an embodiment of the present invention, a depth of a channel constituting the microchannel in the separator may be between 0.2 mm and 1.5 mm.

In order to achieve the above technical problem, another embodiment of the present invention provides a method for designing a microchannel by a channel interval optimal design algorithm.

A method for designing a microchannel according to an optimal channel spacing design algorithm according to an embodiment of the present invention includes: setting boundary conditions and physical properties for simulation analysis of a fluid flowing through the microchannel and simulating the same; developing an algorithm defined by the following Equation 1 to develop an algorithm for deriving an optimal channel spacing of the microchannel; and passing a fluid through a parallel microchannel having the same spacing, adjusting inflow flow rate and output current density conditions, verifying performance of the algorithm, and setting an optimal microchannel spacing.

$${D}_{h , redeslgn , i} = {C ( \overline{Re} / {Re}_{i} )}^{1 / 3} {D}_{h , i} + {w}_{mg} [ mm ] \qquad [ Equation 1 ]$$

i is the channel number, D_{h,redesign,i} is the newly calculated hydraulic diameter of the i-th channel, C is a correction factor making the sum of actual channel spacing and the sum of calculated channel spacing to be equal, R̅e̅ is the average Reynolds number for all channels, Reᵢ is the Reynolds number of the i-th channel, D_{h,i} is the existing hydraulic diameter of the i-th channel, and w_{mg} is a minimum guaranteed channel width which is the minimum width that ensures the channel does not become narrower than this value, even when the channel width is adjusted.

Also, according to an embodiment of the present invention, in the simulating step, the boundary conditions set for the simulation analysis may be a cathode inlet mass flow rate of 1.61×10⁻⁶ (kg/s) to 1.288×10⁻⁵ (kg/s) and an anode inlet mass flow rate of 1.845×10⁻⁷ (kg/s) to 1.476×10⁻⁶ (kg/s), and preferably, the cathode inlet mass flow rate is 3.22×10⁻⁶ (kg/s) and the anode inlet mass flow rate is 3.69×10⁻⁷ (kg/s).

Also, according to an embodiment of the present invention, in the simulating step, the physical property values set for the simulation analysis may be as follows: a density of the separator is 4640 kg/m³, a specific heat is 300 J/kgK, a thermal conductivity is 2.2 W/mK, an electrical conductivity is 4000000 simens/m, and a porosity is 0; a density of the anode is 4760 kg/m³, a specific heat is 377 J/kgK, a thermal conductivity is 11 W/mK, an electrical conductivity is 28586 simens/m, and a porosity is 0.3; a density of the electrolyte is 6000 kg/m³, a specific heat is 100 J/kgK, a thermal conductivity is 2.7 W/mK, an electrical conductivity is 1.42 simens/m, and a porosity is 0; and a density of the cathode is 4640 kg/m³, a specific heat is 377 J/kgK, a thermal conductivity is 2.37 W/mK, an electrical conductivity is 12098 simens/m, and a porosity is 0.3.

Also, according to an example of the present invention, in the step of developing the algorithm, an algorithm for calculating a minimum guaranteed channel spacing can be developed from the Hagen-Poiseuille equation, which is a law relating to the flow rate of a viscous fluid flowing through a tube.

Also, according to an example of the present invention, in the step of setting the optimal fine flow channel gap, the inflow flow rate condition may be half (0.5 \dot{m}), twice (2 \dot{m}), or four times (4 \dot{m}) the existing flow rate (\dot{m}).

Also, according to an example of the present invention, in the step of setting the optimal microporous channel interval, the output current density condition may be 6000 A/m² to 10000 A/m².

### Effects of the Invention

A fuel cell including a separator designed by a fine channel design method using a channel interval optimal design algorithm according to an example of the present invention can be designed by calculating an optimal channel interval through the algorithm, and the temperature reduction, temperature distribution, and flow distribution uniformity of the fluid can be improved through the designed optimal channel interval.

The effects of the present invention are not limited to the above-mentioned effects, and it should be understood that the present invention includes all effects inferable from the detailed description of the present invention or the constitution of the invention described in the claims.

### BRIEF DESCRIPTION OF THE DRAWINGS

FIGS. 1A and 1B are a view illustrating a lattice shape and a reactant flow direction in a terminal cross-sectional dimension and a design method of each component of a solid oxide fuel cell (SOFC) assembly of the present invention.

FIG. 2 is a cross-sectional view illustrating a flow path shape and design parameters of an electrode part in a method of designing a solid oxide fuel cell (SOFC) assembly according to the present invention.

FIG. 3 is a flowchart illustrating a method of designing a microchannel by a channel spacing optimal design algorithm of the present invention.

FIG. 4 is a flowchart for optimizing a channel interval in a design method of a solid oxide fuel cell (SOFC) assembly of the present invention.

FIGS. 5A and 5B are a diagram illustrating a model and a comparison with experimental results to verify the validity of the analysis results in the design method of the solid oxide fuel cell (SOFC) assembly of the present invention.

FIG. 6 is a view showing velocity and temperature distributions in a cathode channel according to various header lengths (LH) in a design method of a solid oxide fuel cell (SOFC) assembly of the present invention.

FIGS. 7A to 7D are a diagram illustrating a velocity distribution in a cathode channel according to w_{mg} for 1in-1out and 2in-1out arrangements in a design method of a solid oxide fuel cell (SOFC) assembly of the present invention, and a distribution of Rei ratio and channel spacing for each channel according to the same.

FIG. 8 is a graph illustrating a result of converting flow uniformity using the Re value of each channel in FIG. 7, and temperature distribution at the cathodes of an original shape and an optimized shape.

FIG. 9 is a view showing a flow uniformity curve of Origin and Optimized shapes under various flow conditions (0.5, 1, 2, 4) for a 1in-1out shape in a design method of a solid oxide fuel cell (SOFC) assembly according to the present invention, and a view showing a channel distance distribution of the Optimized shape at each flow rate.

FIG. 10 is a graph showing the flow uniformity curves of the original and optimized shapes under various current density conditions (6000 A/m², 8000 A/m², 10000 A/m²) for a 1in-1out shape in the SOFC assembly design method according to the present invention, and a graph showing the channel spacing distribution of the optimized shape at each flow rate.

FIG. 11 illustrates IV and IP curve graphs of the optimized and original shapes selected in FIG. 10.

FIG. 12 is a view showing a temperature distribution of a heat exchanger having a heat source of 120 W (286,321 W/m²) using a flow path designed by the original shape and the algorithm as a shape.

### DETAILED DESCRIPTION OF THE INVENTION

Hereinafter, the present invention will be described with reference to the accompanying drawings. However, the present invention may be implemented in various different forms, and thus is not limited to the examples described herein. In the drawings, parts irrelevant to the description are omitted for clear description, and like reference numerals denote like elements throughout the specification.

Throughout the specification, when a part is referred to as being “connected to” another part, it includes not only the direct connection but also the indirect connection through another member. Also, when a part “comprises” a component, it means that it can further include another component unless otherwise stated, and does not exclude the other component.

The terms used in the present specification are used only to describe a specific example, and are not intended to limit the present invention. The singular expression includes the plural expression unless it is clearly meant otherwise in the context. In the present specification, terms such as “comprise” or “have” are intended to designate the existence of features, numbers, steps, operations, components, parts, or combinations thereof described in the specification, but it should be understood that they do not preclude the existence or addition of one or more other features, numbers, steps, operations, components, parts, or combinations thereof.

Hereinafter, the present invention will be described with reference to the drawings presented in the present specification. For reference, the drawings may be exaggerated to describe the features of the present invention. In this case, it is desirable to be interpreted in light of the entire content of the present specification.

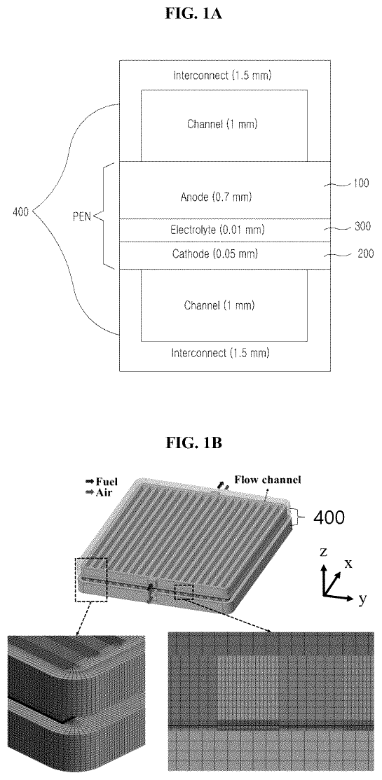

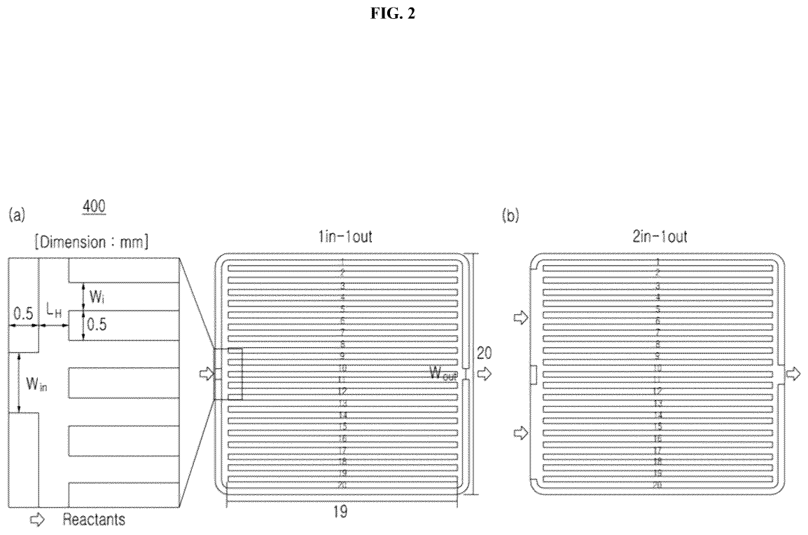

FIGS. 1A, 1B and FIG. 2, a fuel cell with an adjusted channel interval of a separator according to an example of the present invention is described.

FIGS. 1A and 1B are a view illustrating a lattice shape and a reactant flow direction in a terminal cross-sectional dimension and a design method of each component of a solid oxide fuel cell (SOFC) assembly of the present invention.

FIG. 2 is a cross-sectional view illustrating a flow path shape and design parameters of an electrode part in a method of designing a solid oxide fuel cell (SOFC) assembly according to the present invention.

A fuel cell with a controlled channel distance of a separator according to an example of the present invention,

An oxidation electrode (100); a reduction electrode (200); an electrolyte (300) positioned between the oxidation electrode and the reduction electrode; and a separator (400) positioned at both ends of the oxidation electrode and the reduction electrode, the separator being formed to surround the oxidation electrode, the reduction electrode, and the electrolyte and including a microchannel through which hydrogen gas and oxygen gas move,

The channel spacing of the microfluidic channels of the separator is designed by an algorithm defined by the following Equation 1.

$${D}_{h , redeslgn , i} = {C ( \overline{Re} / {Re}_{i} )}^{1 / 3} {D}_{h , i} + {w}_{mg} [ mm ] \qquad [ Equation 1 ]$$

i is the channel number, D_{h,redesign,i} is the newly calculated hydraulic diameter of the i-th channel, C is a correction factor making the sum of actual channel spacing and the sum of calculated channel spacing to be equal, R̅e̅ is the average Reynolds number for all channels, Reᵢ is the Reynolds number of the i-th channel, D_{h,i} is the existing hydraulic diameter of the i-th channel, and w_{mg} is a minimum guaranteed channel width which is the minimum width that ensures the channel does not become narrower than this value, even when the channel width is adjusted.

The above-described oxidation electrode, reduction electrode, and electrolyte may refer to a fuel cell layers, and the fuel cell layers of the present invention is not limited to a specific type, but includes an oxidation electrode, a reduction electrode, and an electrolyte, and can be used without limitation in the case of a layers having a characteristic that degrades the performance of the fuel cell when heat is generated during operation.

The fuel cell with the adjusted channel of the separator of the present invention can be proposed as a type capable of efficient heat generation management in a fuel cell requiring such heat management.

In this case, the electrolyte may be a solid oxide electrolyte material, and may include zirconium oxide, gadolinium-doped ceria or scandia-stabilized zirconia. The electrolyte may also include Nafion, polybenzimidazole or hydrocarbon-based electrolyte materials used in polymer electrolyte fuel cells as well as molten carbonate fuel cells using lithium-potassium carbonate or lithium-sodium-potassium carbonate.

Also, the fuel cell of the present invention may include a separator (400) located at both ends of the oxidant electrode and the reductant electrode in the fuel cell layers for efficient heat generation management.

At this time, the separator (400) may be formed to surround the oxidation electrode, the reduction electrode, and the electrolyte and may include a micro-channel through which hydrogen gas and oxygen gas move.

At this time, the channel interval of the microchannel of the separator is designed by an algorithm defined by the following Equation 1.

$${D}_{h , redeslgn , i} = {C ( \overline{Re} / {Re}_{i} )}^{1 / 3} {D}_{h , i} + {w}_{mg} [ mm ] \qquad [ Equation 1 ]$$

i is the channel number, D_{h,redesign,i} is the newly calculated hydraulic diameter of the i-th channel, C is a correction factor making the sum of actual channel spacing and the sum of calculated channel spacing to be equal, R̅e̅ is the average Reynolds number for all channels, Reᵢ is the Reynolds number of the i-th channel, D_{h,i} is the existing hydraulic diameter of the i-th channel, and w_{mg} is a minimum guaranteed channel width which is the minimum width that ensures the channel does not become narrower than this value, even when the channel width is adjusted.

At this time, the algorithm defined by Equation 1 was developed by improving the Poiseuille's law, which is a rule for the flow rate of a viscous fluid flowing through a tube, and a detailed description will be given later in the method for designing a microchannel according to the optimal design algorithm for channel spacing.

FIGS. 1A and 1B are a view showing a longitudinal cross-section and grid shape, and a reactant inflow direction, of an SOFC shape used for simulation according to a method of designing a flat-plate type SOFC assembly according to the present invention, wherein for five layers, heights of a connector and a channel at both ends are 1.5 mm and 1 mm, respectively.

Also, for the central PEN (Positive electrode-Electrolyte-Negative Electrode) structure, an anode-supported SOFC was selected to maximize the output power performance and minimize the PEN manufacturing cost, and the anode (oxidation electrode), electrolyte, and cathode (reduction electrode) are 0.7 mm, 0.01 mm, and 0.05 mm, respectively.

And, in order to improve the uniform temperature distribution and output performance of the SOFC, a counter-flow in which hydrogen and oxygen face each other was selected as a flow direction. A dense grid was generated in the channel to obtain accurate simulation results for the flow rate passing through the channel, and a plurality of grid layers were formed in the PEN to describe the electrochemical reaction.

FIG. 2 is a cross-sectional view showing a flow path shape and design variables of an electrode part in a method for designing an SOFC assembly according to the present invention.

FIG. 2 shows a cross-sectional view of a connector for a linear channel shape used in a simulation program according to a method of designing a planar SOFC assembly according to the present invention, wherein 19 linear ribs of 0.5 mm×19 mm are inside the channel, resulting in 20 channels from #1 to #20.

At this time, the euro has a 1in-1out having one inlet and one outlet and a 2in-1out shape having two inlets and one outlet. For 1in-1out, the inlet (Win) and outlet (Wout) are 1 mm, and for 2in-1out, the inlet and outlet are 8 mm and 1.5 mm.

At this time, the width of the inlet and outlet of 2in-1out is designed to minimize the average temperature of the PEN through pre-optimization. The optimal shape can be selected by analyzing the results derived from simulations for various header lengths and channel intervals (wi) of each channel.

In addition, the PEN is designed to be 19 mm×19 mm with the same center as the connector.

At this time, in the present invention, the separator may have an adjustable distribution header spacing of the microchannel inlet, and the distribution header spacing of the microchannel inlet of the separator may be between 0.5 (mm) and 2.5 (mm).

At this time, when the distance of the distribution header of the fine flow path inlet part of the separator is between 0.5 (mm) and 2.5 (mm), cooling and heating by air are appropriate, and thus performance can be improved. If the distance of the distribution header is less than 0.5 (mm), there may be a problem in that sufficient space for distribution of the flow rate introduced from the inlet is not secured, and thus the flow rate is concentrated in the central channel. If it exceeds 2.5 (mm), there may be a problem in that the flow rate is concentrated in the central channel, resulting in performance degradation.

The microchannel of the separator of the present invention has a parallel type, serpentine type, or spiral type shape.

At this time, the shape of the microchannel is a shape having an inlet, an outlet, and a channel, and is not limited to the parallel type, serpentine type, or spiral type described above, and can be used.

In addition, in the separation plate of the present invention having the specifications of FIGS. 1A, 1B and FIG. 2, a minimum guaranteed channel interval (w_{mg}) of the channel may be between 0.225 mm and 0.25 mm by the algorithm defined by Equation 1 above.

At this time, the minimum guaranteed channel interval (w_{mg}) means that when a large amount of fluid flows into the channel at a very high flow rate, problems may occur due to a decrease in electrochemical reaction and non-uniform cooling effect, so the acceleration of the flow rate should be controlled by maintaining a minimum channel interval.

At this time, in the present invention, when the minimum guaranteed channel interval (w_{mg}) is less than 0.225 mm, there may be a problem that the flow rate is concentrated in a channel relatively far from the inlet, and when it exceeds 0.25 mm, there may be a problem that the flow rate is concentrated in a channel relatively near the inlet, so the minimum guaranteed channel interval (w_{mg}) may be 0.225 mm to 0.25 mm.

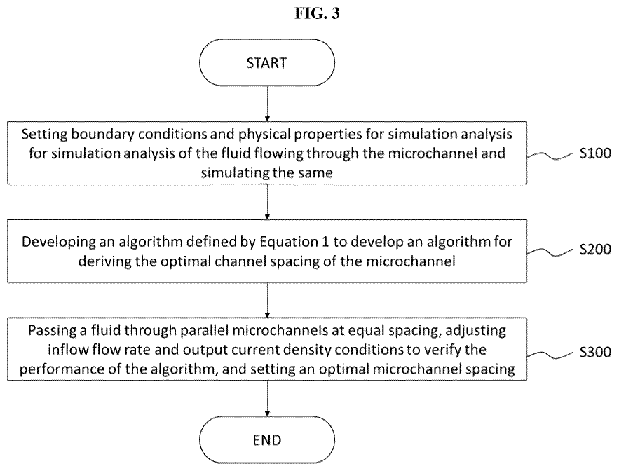

Referring to FIG. 3, a method for designing a microchannel by a channel gap optimal design algorithm according to another example of the present invention will be described.

FIG. 3 is a flowchart illustrating a method of designing a microchannel by a channel spacing optimal design algorithm of the present invention.

Referring to FIG. 3, a method for designing a microchannel according to an optimal channel spacing design algorithm in an example of the present invention includes:

Setting boundary conditions and physical properties for simulation analysis of fluid flowing through the microchannel and simulating the same; Developing an algorithm defined by the following Equation 1 for deriving an optimal channel spacing of the microchannel; And passing a fluid through the parallel microchannels having the same spacing, adjusting inflow flow rate and output current density conditions, verifying performance of the algorithm, and setting an optimal microchannel spacing.

$${D}_{h , redeslgn , i} = {C ( \overline{Re} / {Re}_{i} )}^{1 / 3} {D}_{h , i} + {w}_{mg} [ mm ] \qquad [ Equation 1 ]$$

i is the channel number, D_{h,redesign,i} is the newly calculated hydraulic diameter of the i-th channel, C is a correction factor making the sum of actual channel spacing and the sum of calculated channel spacing to be equal, R̅e̅ is the average Reynolds number for all channels, Reᵢ is the Reynolds number of the i-th channel, D_{h,i} is the existing hydraulic diameter of the i-th channel, and w_{mg} is a minimum guaranteed channel width which is the minimum width that ensures the channel does not become narrower than this value, even when the channel width is adjusted.

In the first step, it may include setting boundary conditions and physical properties for simulation analysis of the fluid flowing through the microchannel and simulating the same (S100).

At this time, the boundary conditions set for the simulation analysis are inlet mass flow rate of the cathode of 1.61×10⁻⁶ (kg/s, H₂ 97 mol %, H₂0 3 mol %) to 1.288×10⁻⁵ (kg/s) and inlet mass flow rate of the anode of 1.845×10⁻⁷ (kg/s; O₂ 21 mol %, N₂ 79 mol %) to 1.476×10⁻⁶ (kg/s), and preferably, the inlet mass flow rate of the cathode is 3.22×10⁻⁶ (kg/s; H₂ 97 mol %, H₂0 3 mol %) and the anode is 3.69×10⁻⁷ (kg/s; O₂ 21 mol %, N₂ 79 mol %), and the outlet condition of the cathode and anode is 0 (Pa; gauge pressure), and the operating temperature may be 973 (K). This describes an actual fuel cell operating environment.

Also, based on the physical properties set for the simulation analysis,

The partition has a density of 4640 kg/m³, specific heat of 300 J/kgK, thermal conductivity of 2.2 W/mK, electrical conductivity of 4000000 S/m, and porosity of 0.

The density of the anode is 4760 (kg/m³), the specific heat is 377 (J/kgK), the thermal conductivity is 11 (W/mK), the electrical conductivity is 28586 (S/m), and the porosity is 0.3.

The density of the electrolyte is 6000 kg/m³, the specific heat is 100 J/kgK, the thermal conductivity is 2.7 W/mK, the electrical conductivity is 1.42 S/m, and the porosity is 0.

The cathode density is set to 4640 kg/m³, specific heat is 377 J/kgK, thermal conductivity is 2.37 W/mK, electrical conductivity is 12098 S/m, and porosity is 0.3.

At this time, the physical property standard is a description of an actual fuel cell.

In the second step, it may include developing an algorithm defined by Equation 1 below to develop an algorithm for deriving the optimal channel spacing of the microchannel. (S200)

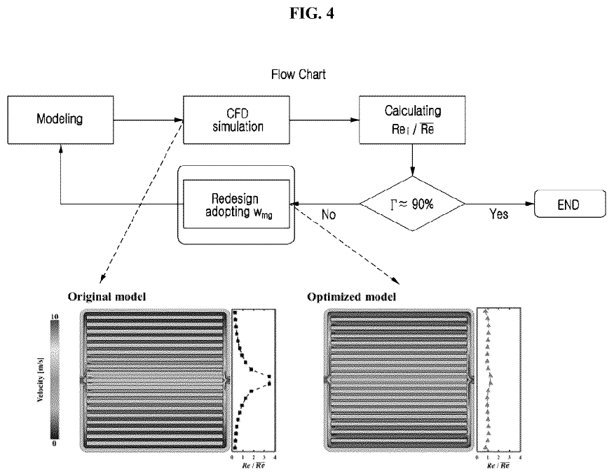

At this time, a specific method for developing an algorithm for deriving an optimal channel spacing of the microfluidic channel of the present invention will be described with reference to FIG. 4.

FIG. 4 is a flowchart for optimizing a channel interval in a design method of a solid oxide fuel cell (SOFC) assembly of the present invention.

FIG. 4 illustrates that a commercial program is used to analyze a solid oxide fuel cell assembly, and using the result, a ratio of a Reynolds number of each channel to an average Reynolds number is calculated.

At this time, the Reynolds number is calculated as in Equation 2 below.

$$Re = \frac{ρ {VD}_{h}}{μ} \qquad [ Equation 2 ]$$

In the above Equation 2, ρ denotes the density of the air electrode flow passage (Kg/m³), V denotes the flow velocity (m/s), Dh denotes the hydraulic diameter (m), and μ denotes the viscosity coefficient (kg/m·s).

The average Reynolds number means an average value for the Re number at the inlet of all channels.

In the prior art, a flow uniformity (Γ) was used, which quantitatively calculates the degree to which reactants flow uniformly into each channel for a linear channel, and in the present invention, this concept is defined as in Equation 3.

$$Γ = 1 - {\{ \frac{1}{n} {\sum }_{i = 1}^{n} {[ \frac{( {Re}_{i} - \overline{Re} )}{\overline{Re}} ]}^{2} \}}^{1 / 2} \times 100 [ \% ] \qquad [ Equation 3 ]$$

n denotes the number of channels in the flow passage and in the present invention, n=20.

In the operation of a solid oxide fuel cell (SOFC), the uniformity of the cathode has a great influence in terms of temperature, and thus the flow uniformity is measured at the cathode side. If the flow uniformity is close to 90%, the optimization process is terminated; otherwise, the optimal channel distance is designed using a redesign algorithm.

FIG. 4 shows an application example for a 1in-1out shape, and illustrates a case where w_{mg} is considered in the redesign algorithm.

The redesigning algorithm is derived from the Poiseuille equation and Equation 2, and the derivation process is as follows.

$${Re}_{i} = \frac{4 ρ Δ {P}_{i}}{128 μL} {D}_{h , i}^{3} ∝ {D}_{h , i}^{3} \qquad [ Equation 4 ]$$

$$\frac{{D}_{h , update , i}}{{D}_{h , i}} = {( \frac{\overline{Re}}{{Re}_{i}} )}^{\frac{1}{3}} \qquad [ Equation 5 ]$$

$${D}_{h , update , i} = {C ( \frac{\overline{Re}}{{Re}_{i}} )}^{\frac{I}{3}} {D}_{h , i} \qquad [ Equation 6 ]$$

$${D}_{h , update , i} = {C ( \frac{\overline{Re}}{{Re}_{i}} )}^{\frac{1}{3}} {D}_{h , i} + {w}_{c w} \qquad [ Equation 7 ]$$

By substituting the Poiseuille equation into the above equation, it may be seen that the Reynolds number of each channel is proportional to the third power of the hydraulic diameter of each channel, as shown in Equation 4.

At this time, a new hydraulic diameter may be calculated such that all channels have a uniform Reynolds number (which is an average Reynolds number in the present invention).

At this time, since the total sum of the channel spacings calculated through Equation 5 is not equal to the total sum of the actual channel spacings (9.5 mm in the present invention), a correction factor for correcting this is multiplied.

In addition, in the shape designed through the optimization process, the mass flow rate of each channel is not equal to the mass flow rate of each channel in the existing shape, and w_{mg} was considered to compensate for this.

w_{mg} has one constant value per shape, and the same value is added for all channels in the optimization process.

The redesign algorithm is used to redesign the channel spacing, and in the process, simulations are performed while changing w_{mg}, and an optimal w_{mg} that provides a uniform Reynolds number distribution is selected and the channel spacing is designed.

In the third step, the method may include passing a fluid through parallel microchannels at equal spacing, adjusting inflow flow rate and output current density conditions to verify the performance of the algorithm, and setting an optimal microchannel spacing. (S300)

At this time, the inflow flow rate condition may be half (0.5 \dot{m}), twice (2 \dot{m}), or four times (4 \dot{m}) the existing flow rate (\dot{m}).

At this time, the reason for setting the inflow flow rate condition to half (0.5 \dot{m}), two times (2 \dot{m}), or four times (4 \dot{m}) of the existing flow rate (\dot{m}) is that it is difficult to fix the inflow flow rate in the actual fuel cell operation, and to select w_{mg} under various operating conditions.

At this time, the output current density condition is 6000 A/m² to 10000 A/m².

At this time, the output current density condition is 6000 A/m² to 10000 A/m² because if the output current density is 6000 A/m² or less, there may be a problem of low output power, and if the output current density exceeds 6000 A/m², there may be a problem of high operating temperature.

Thus, the microchannel design method using the channel interval optimal design algorithm of the present invention can derive an optimal design solution that applies a minimum guaranteed channel interval to suppress excessive channel shape changes, thereby improving fluid temperature reduction, temperature distribution, and flow distribution uniformity.

Hereinafter, the present invention will be described in more detail with reference to Preparation Examples and Experimental Examples. These Preparation Examples and Experimental Examples are only provided to illustrate the present invention, and the scope of the present invention is not limited by these Preparation Examples and Experimental Examples.

Preparation example: Manufacture of fuel cell with controlled channel distance of separator

The present invention is largely divided into a separator, an electrode part, and an electrolyte, and the separator is composed of an anode and a cathode separator, and the electrode part is composed of an anode and a cathode, so five layers form one cell, and the fuel cell structure is used as an analysis model.

First, referring to FIGS. 1A and 1B, for a fuel cell layers (oxidation electrode, electrolyte, reduction electrode) of a center PEN structure with a size of 19 mm×19 mm, the oxidation electrode, electrolyte, and cathode have sizes of 0.7 mm, 0.01 mm, and 0.05 mm, respectively.

Also, the connection member and the channel of the fuel cell layers may each have a height of 1.5 mm and 1 mm to be composed of 5 layers.

Further, the shape of the rib between the connector and the electrode part is a straight channel having 20 channels, and the channels are arranged at equal intervals of 0.475 mm.

In addition, referring to a cross-sectional view of a connecting member regarding a linear channel shape used in the simulation program of FIG. 2, there are 19 linear ribs of 0.5 mm×19 mm in the channel, resulting in 20 channels from No. 1 to No. 20.

At this time, the euro has a 1in-1out shape with one inlet and one outlet, and a 2in-1out shape with two inlets and one outlet.

In this case, for 1in-1out, the inlet (Win) and outlet (Wout) are 1 mm, and for 2in-1out, the inlet and outlet are 8 mm and 1.5 mm, respectively.

At this time, the width of the 2in-1out inlet and outlet is designed to minimize the average temperature of the PEN through pre-optimization.

### EXPERIMENTAL EXAMPLES

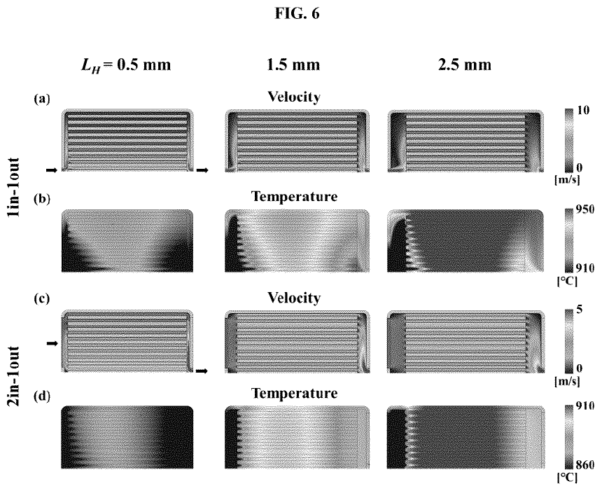

FIG. 6 is a diagram illustrating the flow uniformity, velocity, and temperature distribution in a cathode channel according to various header lengths (LH) in a method of designing an SOFC assembly according to the present invention.

Referring to FIG. 6, as mentioned above, simulation results under a condition of 6000 A/m² are shown for a shape having various header lengths in order to confirm performance according to an increase in the length of a flow path. The header lengths are 0.5 mm, 1.5 mm, and 2.5 mm, and as the header length increases, it can be confirmed that a flow rate uniformity increases from 5.7% to 57% in the case of 1in-1out and from 48% to 96.11% in the case of 2in-1out. However, as the flow rate uniformity increases, an average temperature inside a cell increases from 919.9° C. to 954.35° C. in the case of 1in-1out and from 867.37° C. to 912.41° C. in the case of 2in-1out.

This is because as the header length increases, the air is heated inside the header, and the average temperature of the air reaching the channel increases. In this study, the average air temperature at the channel inlet increases from 887.15° C. to 904.35° C. for the 1in-1out case, and from 834.75° C. to 871.25° C. for the 2in-1out case. Therefore, the method of installing veins and ridges has a trade-off between output power performance and temperature, so it is not suitable.

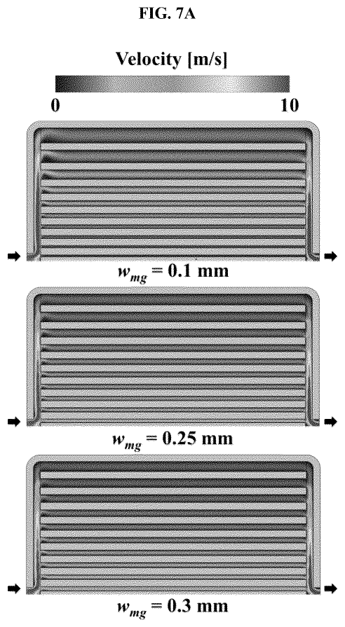

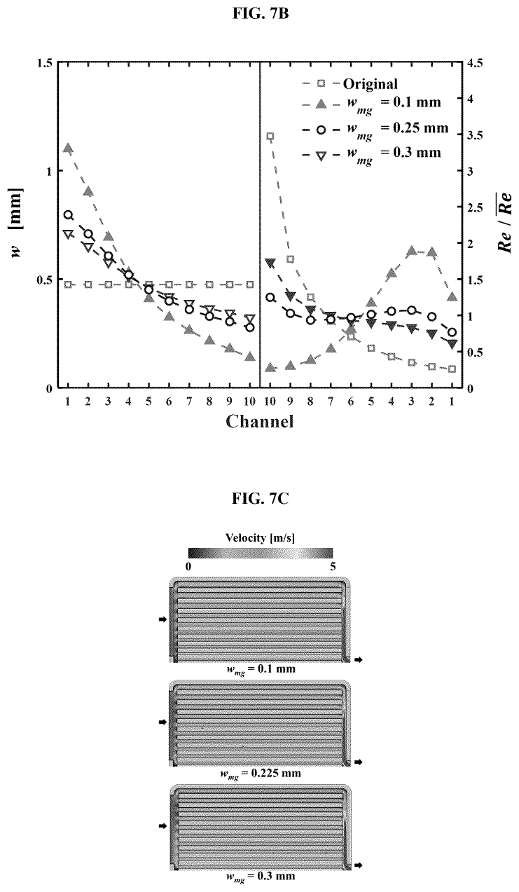

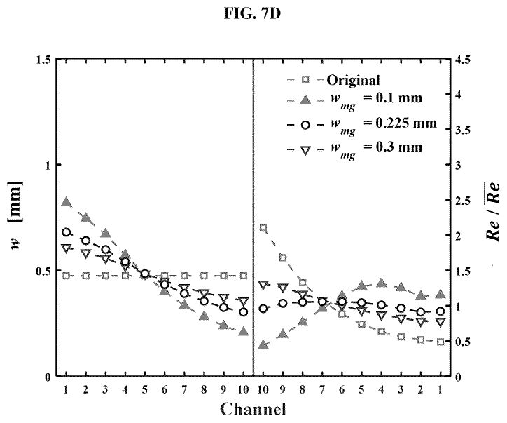

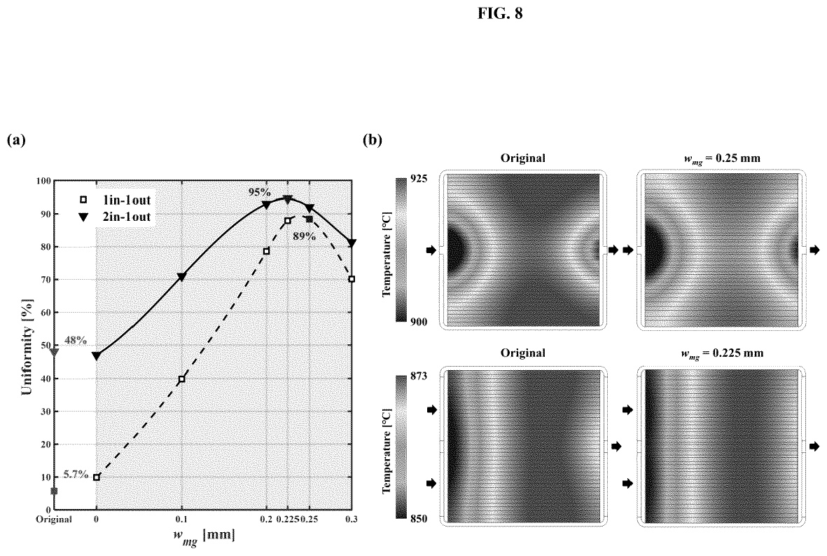

FIGS. 7A to 7D are a diagram illustrating a velocity distribution in a cathode channel according to w_{mg} for 1in-1out and 2in-1out arrangements in a method of designing an SOFC assembly according to the present invention, and a distribution of a ratio of a Reynolds number of a channel to a channel spacing and an average Reynolds number in each channel.

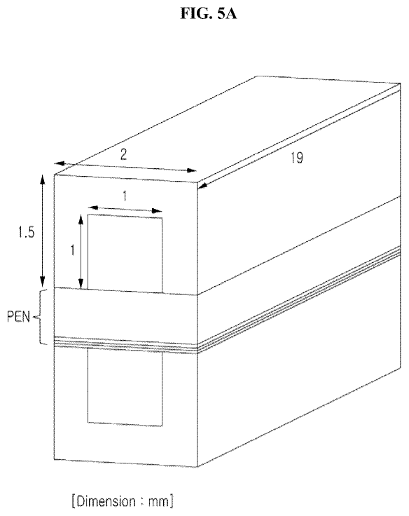

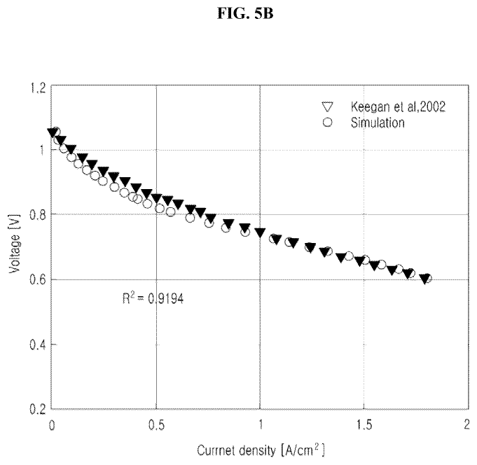

FIGS. 7A to 7D show the velocity distribution of the cathode designed for various w_{mg} under the condition of 6000 A/m² from FIGS. 5A and 5B, channel pitch, and Reynolds number distribution curve.

As can be seen in FIGS. 5A and 5B, for both models, it can be seen that the original shape has a concentrated flow rate in the central channel. The channel spacing changes through the optimization algorithm, and the channel spacing and Reynolds number distribution change according to w_{mg}.

For all cases, it can be seen that the channel spacing is narrowed in the redesigned algorithm with a high Reynolds number ratio and widened with a low ratio. For both shapes, when w_{mg} is 0.1 mm, the channel spacing in the center becomes very narrow, so that the flow rate is distributed to the channels at both ends having relatively wide channel spacing, and accordingly, the center portion has a very low Reynolds number ratio and both ends have a high Reynolds number ratio.

Therefore, w_{mg} needs to be increased to widen the channel spacing in the center. However, when w_{mg} is 0.3 mm, the center has too wide channel spacing such that the entire flow passes through the center channel, resulting in a high Reynolds number ratio in the center and a low Reynolds number ratio at both ends, contrary to the above situation.

Therefore, it is important for w_{mg} to have an appropriate value, and in the present invention, it can be seen that in the case of 1in-1out, w_{mg} has a value of 0.25 mm, and in the case of 2in-1out, w_{mg} has a value of 0.225 mm, and has the most uniform Reynolds distribution throughout the channel.

FIG. 8 is a graph illustrating a result of converting flow uniformity using the Re value of each channel in FIGS. 7A to 7D, and temperature distribution at the cathodes of an original shape and an optimized shape.

FIG. 8 shows that for each shape, the flow uniformity in the optimized model increased from 5.7% to 89% and from 48% to 95%.

In addition, it was found that the average temperature of the PEN was reduced by 3° C. and 1° C. for each case, and the temperature distribution was also uniform. In particular, it was confirmed that the temperature was uniform at each corner of the cell where breakage occurs due to the highest thermal stress.

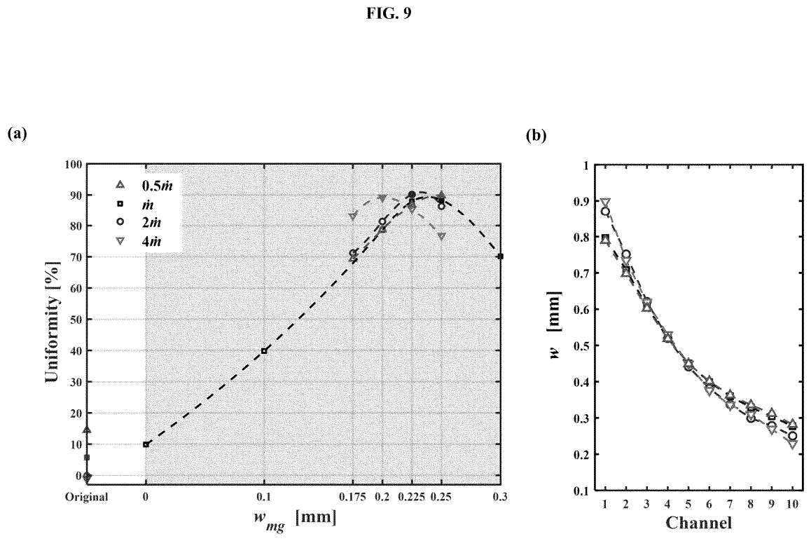

FIG. 9 is a diagram showing the flow uniformity curves of the original and optimized shapes under various flow conditions (0.5 \dot{m}, \dot{m}, 2 \dot{m}, 4 \dot{m}) for the 1in-1out shape in the SOFC assembly design method according to the present invention, and a diagram showing the channel interval distribution of the optimized shape at each flow rate (where the inflow mass flow rate m is 3.22e-6 (kg/s) for the cathode and 3.69e-7 (kg/s) for the anode).

Referring to FIG. 9, simulation and optimization were performed under various inflow flow rate conditions for a 1in-1out shape based on the flow rate condition (\dot{m}) of the simulation performed. At this time, the Reynolds numbers at the cathode inlet under the conditions of 0.5 \dot{m}, \dot{m}, 2 \dot{m}, and 4 \dot{m} are 9.3, 20, 37, and 75, respectively.

As the inflow flow rate increases, the w_{mg} decreases, which is to make the channel spacing in the center narrower to distribute the flow rate concentrated in the central channel to both ends. For all inflow flow rates, it can be confirmed that the flow rate uniformity is improved to about 90%.

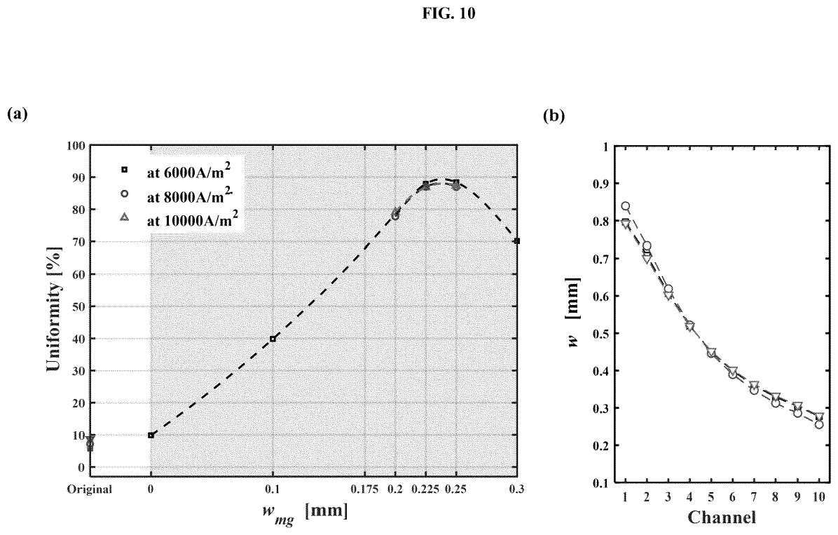

FIG. 10 is a graph showing the flow uniformity curves of the original and optimized shapes under various current density conditions (6000 A/m², 8000 A/m², 10000 A/m²) for a 1in-1out shape in the SOFC assembly design method according to the present invention, and a graph showing the channel spacing distribution of the optimized shape at each flow rate.

Referring to FIG. 10, along with the current density condition (6000 A/m²) of the simulation performed above, the results of flow uniformity according to optimization for various current density conditions are shown, and it can be confirmed that the performance is improved with a flow uniformity of about 90% for the optimal w_{mg} under each current density condition.

In addition, it can be seen that the tendency of flow uniformity according to w_{mg} under each current density condition appears very similar, and through this, it can be seen that the current density condition has little influence on w_{mg}. Through the above results, in the optimization process through the algorithm, if the operating conditions other than the operating current density are the same, one optimized shape can be selected.

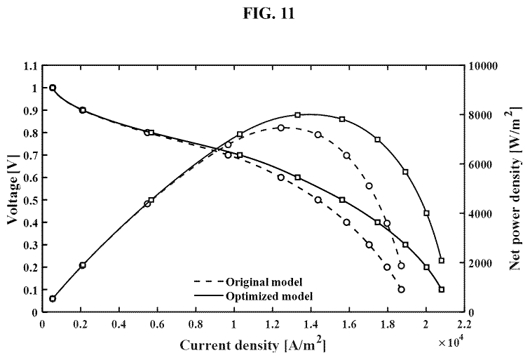

FIG. 11 illustrates IV and IP curve graphs of the optimized and original shapes selected in FIG. 10.

Referring to FIG. 11, in the SOFC, a current density generated according to stability of a device under operation varies, and thus, in order to check a degree of performance improvement for a shape, a performance comparison for an IV curve needs to be performed. The IV curve for the optimal shape selected under the various current density conditions of FIG. 10 shows a performance with a maximum error of 0.04%.

Therefore, it can be concluded that there is no significant performance difference even if an optimized shape at any current density is used. As shown in FIG. 10, it can be confirmed that the optimal shape selected through channel interval optimization has 7% improved performance compared to the Origin model.

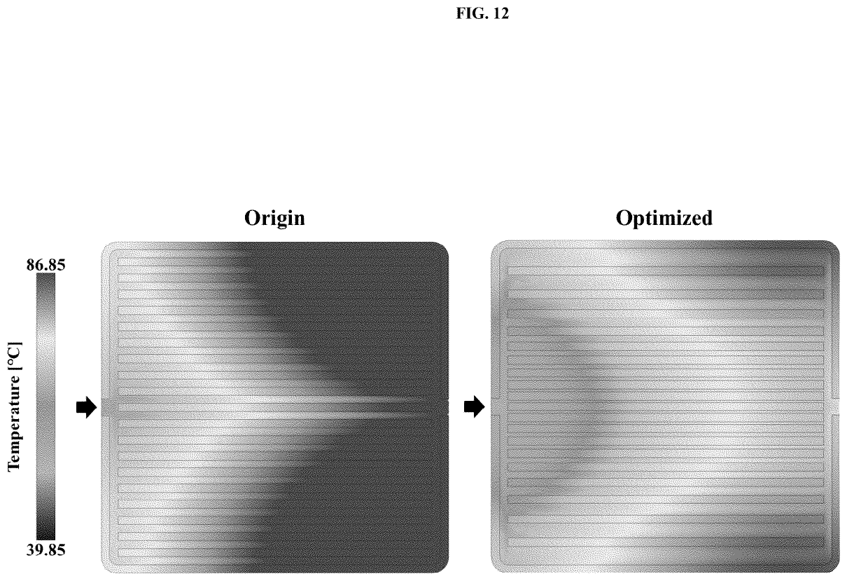

FIG. 12 illustrates the temperature distribution at the interface between the cooling air and the heat exchanger plate for the analysis of a heat exchanger having a heat source of 286,321 W/m², to which the original shape and the shape to which the algorithm is applied. In this case, water at 39.85° C. was introduced as a refrigerant at 1.2 m/s.

Referring to FIG. 12, it can be seen that the performance is significantly improved in terms of temperature distribution as the flow rate concentrated in the central channel is dispersed to the channels at both ends. In particular, the average air temperatures of the Original shape and the Optimized shape are 66.73° C. and 56.68° C., respectively, and the latter shape is reduced by about 10° C.

The above description of the present invention is for illustrative purposes, and a person having ordinary knowledge in the technical field to which the present invention pertains can easily understand that the present invention can be modified into other specific forms without changing the technical spirit or essential features of the present invention. Therefore, the examples described above should be understood as being illustrative in all aspects and not limiting. For example, each component described as a single unit may be implemented in a distributed manner, and similarly, components described as being distributed may also be implemented in a combined form.

The scope of the present invention is defined by the claims described below, and it should be interpreted that all changes or modified forms derived from the meaning and scope of the claims and equivalent concepts are included in the scope of the present invention.

What is claimed is:

1. A fuel cell with adjusted channel distance of a separator comprising:
oxidizing electrode;
reduction electrode;
an electrolyte positioned between the oxidation electrode and the reduction electrode; and
a separator positioned at both ends of the oxidation electrode and the reduction electrode, surrounding the oxidation electrode, the reduction electrode, and the electrolyte, and having a microchannel through which hydrogen gas and oxygen gas move;
wherein a channel distance of the microchannel of the separator is designed by an algorithm defined by the following Equation 1,
$${D}_{h , redeslgn , i} = {C ( \overline{Re} / {Re}_{i} )}^{1 / 3} {D}_{h , i} + {w}_{mg} [ mm ] \qquad [ Equation 1 ]$$
i is the channel number, D_{h,redesign,i} is the newly calculated hydraulic diameter of the i-th channel, C is a correction factor making the sum of actual channel spacing and the sum of calculated channel spacing to be equal, R̅e̅ is the average Reynolds number for all channels, Reᵢ is the Reynolds number of the i-th channel, D_{h,i} is the existing hydraulic diameter of the i-th channel, and w_{mg} is a minimum guaranteed channel width which is the minimum width that ensures the channel does not become narrower than this value, even when the channel width is adjusted.

2. The fuel cell of claim 1,
the electrolyte is a solid oxide electrolyte material, comprising zirconium oxide, gadolinia-doped ceria or scandia-stabilized zirconia, wherein a channel distance of the separator is controlled.

3. The fuel cell of claim 1,
wherein a minimum guaranteed channel distance (w_{mg}) of the microchannel in the separator is 0.225 mm to 0.25 mm.

4. The fuel cell of claim 1,
the separator is characterized in that a distribution header of an inlet of the microchannel is adjusted.

5. The fuel cell of claim 4,
wherein a spacing of the distribution header of the inlet of the microchannel of the separator is between 0.5 mm and 2.5 mm.

6. The fuel cell of claim 1,
wherein the microchannel of the separator comprises a parallel type, a serpentine type, or a spiral type.

7. The fuel cell of claim 1,
wherein a depth of the microchannel in the separator is 0.2 (mm) to 1.5 (mm).

8. A method for designing a microchannel by an optimal channel spacing design algorithm comprises:
setting boundary conditions and physical properties for simulation analysis of a fluid flowing through a microchannel;
simulating the fluid flowing through the microchannel;
developing an algorithm defined by Equation 1 below to derive an optimal channel spacing of the microchannel; and
setting an optimal microchannel spacing by passing a fluid through parallel microchannels having the same spacing, and verifying the performance of the algorithm by adjusting the inflow flow rate and the output current density conditions,
$${D}_{h , redeslgn , i} = {C ( \overline{Re} / {Re}_{i} )}^{1 / 3} {D}_{h , i} + {w}_{mg} [ mm ] \qquad [ Equation 1 ]$$
i is the channel number, D_{h,redesign,i} is the newly calculated hydraulic diameter of the i-th channel, C is a correction factor making the sum of actual channel spacing and the sum of calculated channel spacing to be equal, R̅e̅ is the average Reynolds number for all channels, Reᵢ is the Reynolds number of the i-th channel, D_{h,i} is the existing hydraulic diameter of the i-th channel, and w_{mg} is a minimum guaranteed channel width which is the minimum width that ensures the channel does not become narrower than this value, even when the channel width is adjusted.

9. The method of claim 8,
wherein in the boundary conditions set for the simulation analysis, an inflow mass flow rate of a cathode is 1.61×10⁻⁶ (kg/s) to 1.288×10⁻⁵ (kg/s), and an inflow mass flow rate of a anode is 1.845×10⁻⁷ (kg/s) to 1.476×10⁻⁶ (kg/s).

10. The method of claim 8,
wherein the criteria of the physical properties set for the simulation analysis comprises:
a partition having density of 4640 kg/m³, specific heat of 300 J/kgK, thermal conductivity of 2.2 W/mK, electrical conductivity of 4000000 S/m, and porosity of 0,
an anode having density of 4760 (kg/m³), specific heat of 377 (J/kgK), thermal conductivity of 11 (W/mK), electrical conductivity of 28586 (S/m), and porosity of 0.3,
an electrolyte having density of 6000 kg/m³, specific heat of 100 J/kgK, thermal conductivity of 2.7 W/mK, electrical conductivity of 1.42 S/m, and porosity of 0,
a cathode having density of 4640 kg/m³, specific heat of 377 J/kgK, thermal conductivity of 2.37 W/mK, electrical conductivity of 12098 S/m, and porosity of 0.3.

11. The method of claim 8,
wherein the algorithm is developed for calculating a minimum guaranteed channel spacing from the Hagen-Poiseuille equation which is a law relating to a flow rate of a viscous fluid flowing through a tube.

12. The method of claim 8,
wherein the inflow flow rate condition is half (0.5 \dot{m}), two times (2 \dot{m}), or four times (4 \dot{m}) that of the existing flow rate (\dot{m}).

13. The method of claim 8,
wherein the output current density condition is 6000 A/m² to 10000 A/m².
